(19) United States
(12) Patent Application Publication
(10) Pub. No.: US 2025/0264507 A1
(43) Pub. Date: Aug. 21, 2025

(54) APPARATUS AND METHOD WITH FREQUENCY DETECTION

(71) Applicant: Samsung Electronics Co., Ltd., Suwon-si (KR)

(72) Inventor: Whan GHANG, Suwon-si (KR)

(73) Assignee: Samsung Electronics Co., Ltd., Suwon-si (KR)

(21) Appl. No.: 18/780,042

(22) Filed: Jul. 22, 2024

(30) Foreign Application Priority Data
Feb. 21, 2024 (KR) 10-2024-0025036

(51) Int. Cl. G01R 23/02; G06F 17/18; G06N 10/40

(52) U.S. Cl. CPC G01R 23/02; G06F 17/18; G06N 10/40

(57) ABSTRACT

A processor-implemented method with frequency detection includes setting a sample cutting parameter, performing sampling in a sampling interval set based on the sample cutting parameter, obtaining a Wasserstein distance between a first probability distribution and a second probability distribution for an available frequency based on a result of the sampling, and determining a frequency, at which the obtained Wasserstein distance is minimum, as an optimal frequency.

### CROSS-REFERENCE TO RELATED APPLICATION(S)

This application claims the benefit under 35 USC § 119 (a) of Korean Patent Application No. 10-2024-0025036, filed on Feb. 21, 2024 in the Korean Intellectual Property Office, the entire disclosure of which is incorporated herein by reference for all purposes.

### BACKGROUND

### 1. Field

The following description relates to an apparatus and method with frequency detection.

### 2. Description of the Related Art

In a quantum computer, qubits may be controlled using the Rabi frequency. The Rabi frequency is a frequency at which the probability amplitudes of two atomic energy levels fluctuate in an oscillating electromagnetic field. The atomic energy levels may be represented by |0>, which is the ground state, and |1> which is the excited state. The Rabi oscillation occurs due to a difference between two energy levels and an applied oscillating electromagnetic field. The qubit states may be controlled by changing the time during which the electromagnetic field is applied. For example, by applying the electromagnetic field during a time corresponding to a period IT of the Rabi oscillation, the qubit state may be changed from |0> to |1> or vice versa (from |1> to |0>). In order to use a generated qubit, it is required to find the Rabi frequency corresponding to the energy level of the qubit. By dividing a sampling interval into several equal sub-intervals and by repeatedly performing a large number of measurements at each sampling point, a probability of measuring zero at a corresponding point may be obtained, and then by drawing a probabilistic graph, a frequency that is well fitted to the probabilistic graph may be found and used as the Rabi frequency.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one or more general aspects, a processor-implemented method with frequency detection includes setting a sample cutting parameter, performing sampling in a sampling interval set based on the sample cutting parameter, obtaining a Wasserstein distance between a first probability distribution and a second probability distribution for an available frequency based on a result of the sampling, and determining a frequency, at which the obtained Wasserstein distance is minimum, as an optimal frequency.

The first probability distribution may be

$$\frac{1}{{\sum }_{j = 1}^{n} {cos}^{2} ( π f {x}_{j} )} {\sum }_{i = 1}^{n} {cos}^{2} ( π f {x}_{i} ) {δ}_{{x}_{i}} ,$$

the second probability distribution may be

$$\frac{1}{{\sum }_{j = 1}^{n} \frac{{a}_{i}}{m}} {\sum }_{i = 1}^{n} \frac{{a}_{i}}{m} {δ}_{{x}_{i}} ,$$

i and j may be integer indexes, f may be the available frequency, m may be a number of sample points, n may be a number of samplings at each sample point, xᵢ may be an amplitude at a sample point i, aᵢ may be a number of times zero appears when samplings are performed m number of times at the sample point i, and δ may be a Dirac delta function.

The first probability distribution may be

$${\sum }_{i = 1}^{n} \frac{1}{n} δ {cos}^{2} ( π f {x}_{i} ) ,$$

the second probability distribution may be

$${\sum }_{i = 1}^{n} \frac{1}{n} δ \frac{{a}_{i}}{m} ,$$

i and j may be integer indexes, f may be the available frequency, m may be a number of sample points, n may be a number of samplings at each sample point, xᵢ may be an amplitude at a sample point i, aᵢ may be a number of times zero appears when samplings are performed m number of times at the sample point i, and δ may be a Dirac delta function.

The sample cutting parameter may include a first cutting value obtained by multiplying a first value by an initial period and a second cutting value obtained by multiplying a second value by the initial period.

The sampling interval may include an interval between the first cutting value and the second cutting value.

The method may include setting a total number of samples N=m×n including the number of sample points m and the number of samplings n at each sample point, wherein m and n are natural numbers.

The number of sample points m and the number of samplings n at each sample point may be adjusted as hyperparameters.

The method may include setting a grid search parameter, and searching for the available frequency based on the set grid search parameter.

In one or more general aspects, a non-transitory computer-readable storage medium may store instructions that, when executed by one or more processors, configure the one or more processors to perform any one, any combination, or all of operations and/or methods disclosed herein.

In one or more general aspects, an apparatus with frequency detection includes one or more processors configured to set a sample cutting parameter, perform sampling in a sampling interval set based on the sample cutting parameter, obtain a Wasserstein distance between a first probability distribution and a second probability distribution for an available frequency based on a result of the sampling, and determine a frequency, at which the obtained Wasserstein distance is minimum, as an optimal frequency.

The first probability distribution may be

$$\frac{1}{{\sum }_{j = 1}^{n} {cos}^{2} ( π {fx}_{j} )} {\sum }_{i = 1}^{n} {cos}^{2} ( π {fx}_{i} ) {δ}_{{x}_{i}} ,$$

the second probability distribution may be

$$\frac{1}{{\sum }_{j = 1}^{n} \frac{{a}_{i}}{m}} {\sum }_{i = 1}^{n} \frac{{a}_{i}}{m} {δ}_{{x}_{i}} ,$$

i and j may be integer indexes, f is the available frequency, m may be a number of sample points, n may be a number of samplings at each sample point, xᵢ may be an amplitude at a sample point i, aᵢ may be a number of times zero appears when samplings are performed m number of times at the sample point i, and δ may be a Dirac delta function.

The first probability distribution may be

$${\sum }_{j = 1}^{n} \frac{1}{n} {δ}_{{cos}^{2}} ( π {fx}_{i} ) ,$$

the second probability distribution may be

$${\sum }_{j = 1}^{n} \frac{1}{n} {δ}_{\frac{{a}_{i}}{m}} ,$$

i and j may be integer indexes, f is the available frequency, m may be a number of sample points, n may be a number of samplings at each sample point, xᵢ may be an amplitude at a sample point i, aᵢ may be a number of times zero appears when samplings are performed m number of times at the sample point i, and δ may be a Dirac delta function.

The sample cutting parameter may include a first cutting value obtained by multiplying a first value by an initial period and a second cutting value obtained by multiplying a second value by the initial period.

The sampling interval may include an interval between the first cutting value and the second cutting value.

The one or more processors may be configured to set a total number of samples N=m×n including the number of sample points m and the number of samplings n at each sample point, wherein m and n are natural numbers.

The one or more processors may be configured to set a grid search parameter, and search for the available frequency based on the set grid search parameter.

The apparatus may include one or more qubits, and a qubit controller configured to control the one or more qubits based on the determined optimal frequency.

In one or more general aspects, a quantum computing device includes a frequency detection apparatus configured to perform sampling in a sampling interval set based on a sample cutting parameter, obtain a Wasserstein distance between a first probability distribution and a second probability distribution for an available frequency based on a result of the sampling and determine a frequency, at which the obtained Wasserstein distance is minimum, as a Rabi frequency, one or more qubits, and a qubit controller configured to control the one or more qubits based on the determined Rabi frequency.

The sample cutting parameter may include a first cutting value obtained by multiplying a first value by an initial period and a second cutting value obtained by multiplying a second value by the initial period.

The frequency detection apparatus may be configured to set a total number of samples N=m×n including a number of sample points m and a number of samplings n at each sample point, wherein m and n are natural numbers.

Other features and aspects will be apparent from the following detailed description, the drawings, and the claims.

### BRIEF DESCRIPTION OF THE DRAWINGS

FIG. 1 is a block diagram illustrating a frequency detection apparatus according to one or more embodiments of the present disclosure.

FIG. 2 is a flowchart illustrating a frequency detection method according to one or more embodiments of the present disclosure.

FIG. 3A is a diagram exhibiting Wasserstein distance's characteristic for detecting phase shift error (or the degree of shift).

FIG. 3B is a diagram explaining a phase shift error.

FIG. 4 is a block diagram illustrating an example in which a frequency detection apparatus is applied to a quantum computing device according to one or more embodiments of the present disclosure.

FIG. 5 is a block diagram illustrating an example in which a frequency detection apparatus is included in an apparatus for calibrating a quantum computing device according to one or more embodiments of the present disclosure.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on”, “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

Unless otherwise defined, all terms used herein including technical and scientific terms have the same meanings as those commonly understood by one of ordinary skill in the art to which this disclosure pertains and based on an understanding of the disclosure of the present application. Terms such as those defined in commonly used dictionaries are to be interpreted as having a meaning that is consistent with their meaning in the context of the relevant art and the disclosure of the present application, and are not to be interpreted in an idealized or overly formal sense unless expressly so defined herein.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

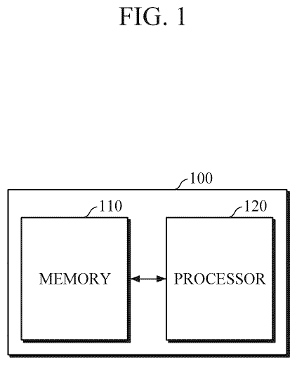

FIG. 1 is a block diagram illustrating a frequency detection apparatus according to one or more embodiments of the present disclosure.

Referring to FIG. 1, a frequency detection apparatus 100 includes a memory 110 (e.g., one or more memories) and a processor 120 (e.g., one or more processors). The frequency detection apparatus 100 may detect the Rabi frequency for controlling the states of qubits in a quantum computing device. However, the frequency detection apparatus 100 is not limited thereto, and may be used in a communication device for detecting a frequency of a communication signal that oscillates at a specific frequency. For convenience of explanation, the following description will be given based on the Rabi frequency.

The memory 110 may store various instructions executed by the processor 120. For example, the memory 110 may include a non-transitory computer-readable storage medium storing instructions that, when executed by the processor 120, configure the processor 120 to perform any one, any combination, or all of operations and/or methods disclosed herein with reference to FIGS. 1-5. In addition, the memory 110 may store data (e.g. hyperparameters, such as a sample number parameter, a sample cutting parameter, a grid search parameter, etc., and a predefined Wasserstein distance function), and the like. Further, the memory 110 may store processing results of the processor 120 (e.g., detected frequency, minimum distance, etc.), data input from a user through an input device, image data acquired by an image capture device, and/or data received from an external device connected through a communication device.

The memory 110 may include Random Access Memory (RAM), such as Dynamic Random Access Memory (DRAM), Static Random Access Memory (SRAM), etc., Read-Only Memory (ROM), flash memory, cache memory, virtual memory, etc., but is not limited thereto.

The processor 120 may execute the instructions stored in the memory 110 and detect the Rabi frequency for controlling qubits in the quantum computing device. The processor 120 may include a main processor, e.g., a central processing unit (CPU) and/or an application processor (AP), etc., an intellectual property (IP) core, and an auxiliary processor, e.g., a graphics processing unit (GPU), an image signal processor (ISP), a sensor hub processor, and/or a communication processor (CP), a Quantum Processing Unit (QPU), which is operable independently from, and/or in conjunction with, the main processor, and the like.

In a typical apparatus and method, the Rabi frequency may be found by drawing a probabilistic graph, in which, in order to measure frequencies with reliable accuracy, the typical apparatus and method must increase the number of samples by repeatedly performing a large number of measurements at sample points corresponding to each amplitude. In addition, the typical apparatus and method must repeat measurements at one amplitude, and when all sample points are different, probability is not derived such that it is difficult for the typical apparatus and method to obtain the Rabi frequency.

In contrast to the typical apparatus and method, an apparatus and method of one or more embodiments may derive the Wasserstein distance function by using frequency information obtained at the sample points, and may detect a frequency at which the Wasserstein distance is minimized as the Rabi frequency. The apparatus and method of one or more embodiments may consider a phase shift error by using the Wasserstein distance. Further, by using sample cutting and/or grid search methods, the apparatus and method of one or more embodiments may improve the accuracy of detecting the Rabi frequency while reducing the number of samples.

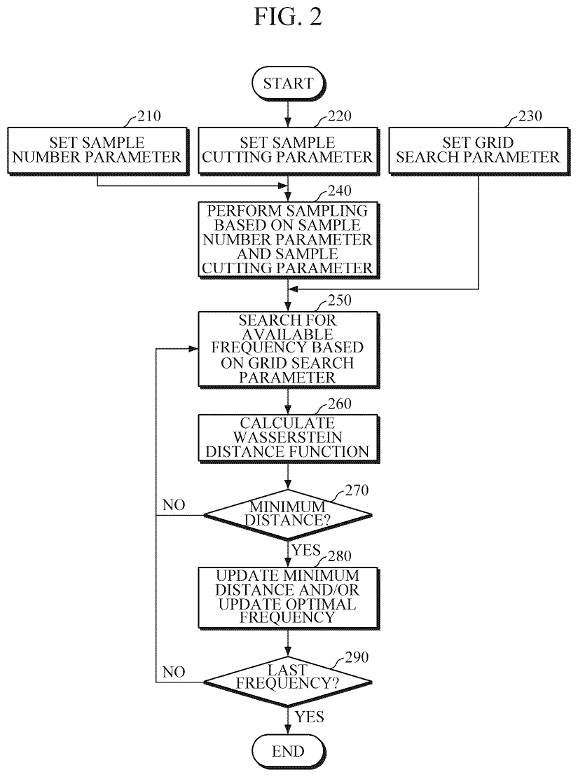

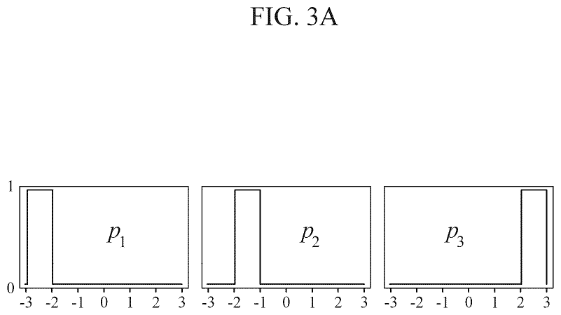

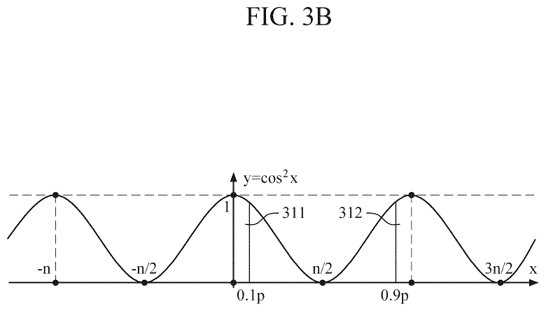

FIG. 2 is a flowchart illustrating a frequency detection method according to one or more embodiments of the present disclosure. FIG. 3A is a diagram explaining Wasserstein distance's characteristic for detecting phase shift error (or the degree of shift). FIG. 3B is a diagram explaining a phase shift error.

FIG. 2 is a flowchart illustrating a frequency detection method performed by the frequency detection apparatus 100 of FIG. 1. Operations 210 to 290 described below may be performed in the order and manner as shown and described below with reference to FIG. 2, but the order of one or more of the operations may be changed, one or more of the operations may be omitted, and/or two or more of the operations may be performed in parallel or simultaneously without departing from the spirit and scope of the example embodiments described herein.

The frequency detection apparatus 100 may set a sample number parameter in operation 210, set a sample cutting parameter in operation 220, and set a grid search parameter in operation 230. The sample number parameter, the sample cutting parameter, and the grid search parameter may be adjusted as hyperparameters.

The sample number parameter may include the number of sample points as to how many sample points are generated and the number of samplings as to how many times samples are taken at each sample point, and the number of sample points and the number of samplings may be optimally adjusted as hyperparameters according to a target Rabi frequency. By setting the total number of samples to N=m×n, the number of sample points m and the number of samplings n at each sample point may be set properly through experimentation while maintaining that N=m×n.

The sample cutting parameter may be used for setting a sampling interval. An interval with a probability close to zero and an interval with a probability close to one provide relatively little information about frequency. Accordingly, by cutting out these intervals so as not to perform sampling in the intervals, sampling may be performed in the remaining intervals. For example, the sample cutting parameter may be defined as a first cutting value and a second cutting value. In this case, an interval between the first cutting value and the second cutting value may be set as a sampling interval, and an interval between zero and the first cutting value and an interval between the second cutting value and one cycle may be set as cut sections in which no sampling is not performed.

The first cutting value may be set to 0.1 p in order to cut out an interval 311 (e.g., as shown in FIG. 3B) where the probability is close to 0, and the second cutting value may be set to 0.9 p in order to cut out an interval 312 (e.g., as shown in FIG. 3B) where the probability is close to 1. These sample cuttings could be made where the probability is close to 0 or 1. In this case, p is a value corresponding to the reciprocal (p=1/f₀) of an initial frequency f₀, and may be preset, as a hyperparameter, to a value close to the Rabi frequency. Further, the values of 0.1 and 0.9 may also be adjusted as hyperparameters.

The grid search parameter may represent the number of frequencies to be input to the Wasserstein distance function for grid search within an available frequency range of the Rabi frequency.

Referring back to FIG. 2, in the sampling intervals that remain after cutting out some intervals based on the set sample cutting parameter, the frequency detection apparatus 100 may measure frequencies by performing sampling based on the set sample number parameter in operation 240.

The frequency detection apparatus 100 may search for an available frequency for grid search in the available frequency range of the Rabi frequency based on a grid search parameter in operation 250. The available frequency range of the Rabi frequency may be preset. For example, when the available frequency range (a,b) is preset and the grid search parameter k is set, the frequency detection apparatus 100 may search for an available frequency by dividing the interval (a,b) into k sub-intervals and sequentially increasing the available frequency at k number of points.

The frequency detection apparatus 100 may determine a Wasserstein distance objective function between a first probability distribution and a second probability distribution for the searched available frequency in operation 260.

For example, the first probability distribution and the second probability distribution may be defined as shown in Equations 1 and 2 below, for example.

$$\frac{1}{{\sum }_{j = 1}^{n} {cos}^{2} ( π {fx}_{j} )} {\sum }_{i = 1}^{n} {cos}^{2} ( π {fx}_{i} ) {δ}_{{x}_{i}} \qquad Equation 1$$

$$\frac{1}{{\sum }_{j = 1}^{n} \frac{{a}_{i}}{m}} {\sum }_{i = 1}^{n} \frac{{a}_{i}}{m} {δ}_{{x}_{i}} \qquad Equation 2$$

In Equations 1 and 2, i and j are integer indexes, f is the available frequency determined in operation 250, m is the number of sample points, n is the number of samplings at each sample point, xᵢ is an amplitude at a sample point i, a; is the number of times zero appears when samplings are performed m number of times at the sample point i, and δ is the Dirac delta function.

In another example, the first probability distribution and the second probability distribution may be defined as shown in Equations 3 and 4 below, for example. The respective probabilities in the first probability distribution and the second probability distribution may be derived by transformation using point measures, such that a principle may be used in which when the probabilities in the first probability distribution and the second probability distribution are sorted to minimize the sum of distances between similar probabilities, the frequencies of the two probability distributions approach each other.

$${\sum }_{j = 1}^{n} \frac{1}{n} {δ}_{{cos}^{2}} ( π {fx}_{i} ) \qquad Equation 3$$

$${\sum }_{i = 1}^{n} \frac{1}{n} {δ}_{\frac{{a}_{i}}{m}} \qquad Equation 4$$

In Equations 3 and 4, i and j are integer indexes, f is the available frequency determined in operation 250, m is the number of sample points, n is the number of samplings at each sample point, xᵢ is an amplitude at a sample point i, aᵢ is the number of times zero appears when samplings are performed m number of times at the sample point i, and δ is the Dirac delta function.

As illustrated in FIG. 3A, distances L¹ and L² between two of probability distributions p₁, p₂, and p₃ are generally the same as shown in the following Equation 5 below, for example. As for a distance L^{p}, only values on the same x-axis are compared, such that a degree of phase shift of the probability distribution may not be measured.

$$\begin{matrix}{\vert p 1 - p 2 \vert}_{{L}^{p}} = {( {\int }_{- 3}^{3} {\vert {p}_{1} ( x ) - {p}_{2} ( x ) \vert}^{p} )}^{\frac{1}{p}} = \sqrt[p]{2} \\ = {\vert p 1 - p 3 \vert}_{{L}^{p}} = {\vert p 2 - p 3 \vert}_{{L}^{p}}\end{matrix} \qquad Equation 5$$

In one or more embodiments of the present disclosure, the Rabi frequency may be detected in consideration of a phase shift error by using the Wasserstein distance and by defining the probability distributions as shown in the above Equations 1, 2, 3 and 4. That is, in Equations 2 and 4, aᵢ/m generally converges to cos²(πf₀xᵢ) when m increases, but when there is a phase shift error e, the value converges to cos²(πf₀xᵢ+e) where f₀ is the Rabi frequency. As described above, when there is a phase shift error, the distance L^{p} is generally vulnerable in detecting the Rabi frequency, but in one or more embodiments, the Rabi frequency which is robust to the phase shift error may be detected by using the Wasserstein distance. In one or more embodiments, the probability distributions used for defining the Wasserstein distance objective function are not limited to the above Equations and may be modified variously.

The frequency detection apparatus 100 may determine in operation 270 whether the Wasserstein distance is minimum at the available frequency f searched in operation 250, and in response to determining that the determined Wasserstein distance is minimum, the frequency detection apparatus 100 may update the minimum distance and may store and/or update the available frequency, searched in operation 250, as an optimal Rabi frequency in operation 280.

The frequency detection apparatus 100 may determine whether there is a next available frequency to be searched based on a grid search parameter in operation 290, and when there is the next available frequency, the frequency detection apparatus 100 may reperform operation 250 and subsequent operations, and if not, the frequency detection apparatus 100 may terminate the operation.

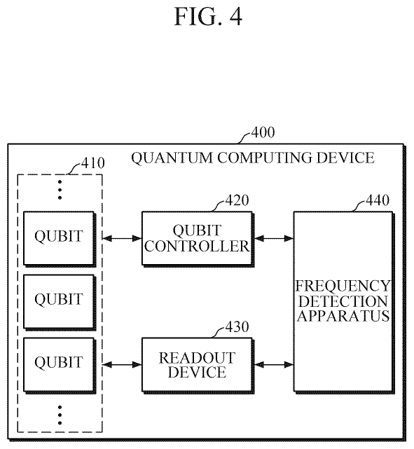

FIG. 4 is a block diagram illustrating an example in which a frequency detection apparatus is applied to a quantum computing device.

Referring to FIG. 4, a quantum computing device 400 may include one or more qubits 410, a qubit controller 420, a readout device 430, and a frequency detection apparatus 440.

The qubits 410 are the basic unit for representing states of quantum objects, such as atoms, ions, neutrons, protons, photons, electrons, and the like. A quantum mechanical phenomenon of entanglement occurs between the qubits 410, and by using the entanglement, information processing may be performed more efficiently than a classical computing device.

The qubit controller 420 may manipulate and control the qubits 410 by using quantum technology. The quantum technology may include superconductivity technology, ion trap technology, optical technology, etc., but is not limited thereto, and may include all techniques for creating quantum objects using quantum mechanics. The qubit controller 420 may change the topological states of the quantum objects. For example, the qubit controller 420 may initialize the qubits 410 to 0 or 1, and may manipulate the quantum states of the qubits 410 by using various quantum operations. Further, the qubit controller 420 may perform quantum operations by applying quantum gates to the qubits 410 and may measure the quantum states of the qubits 410. In addition, the qubit controller 420 may control the frequency detection apparatus 440 to detect the Rabi frequency, and may control the states of the qubits 410 by applying an optimal Rabi frequency detected by the frequency detection apparatus 440.

The readout device 430 may measure the states of the qubits 410, and may read out and write results from the qubits 410.

The frequency detection apparatus 440 may detect an optimal Rabi frequency by using a combination of a sample cutting method and a grid search method based on the Wasserstein distance between two pre-defined probability distributions, as described above.

The quantum computing device 400 may further include a storage device, a communication device, an output device, an image capture device for acquiring images, a sensor device (e.g., acceleration sensor, gyroscope, magnetic field sensor, proximity sensor, illuminance sensor, fingerprint sensor, etc.) for detecting various data, an input device (e.g., a microphone, a mouse, a keyboard, and/or a digital pen (e.g., a stylus pen, etc.), etc.) for receiving instructions and/or data to be used from a user, and the like.

The storage device may store various instructions executed by the quantum computing device 400. In addition, the storage device may store processing results of the quantum computing device 400, data input from a user through the input device, image data acquired by the image capture device, and/or data received from an external device connected through a communication device. The storage device may include a computer-readable storage medium, e.g., Random Access Memories (RAM), Dynamic Random Access Memories (DRAM), Static Random Access Memories (SRAM), magnetic hard disk, optical disk, flash memory, Electrically Programmable Read Only Memories (EPROM), and/or other types of computer-readable storage media known in this art.

The communication device may support establishment of a direct (e.g., wired) communication channel and/or a wireless communication channel between the electronic device and other electronic device, a server, and/or the sensor device within a network environment, and performing of communication via the established communication channel, by using various communication techniques. The communication device may transmit the data processed by the quantum computing device 400 and/or the images captured by the image capture device, and the like to another electronic device. In addition, the communication device may receive data, such as images to be processed and/or natural language, etc., from a cloud device and/or another electronic device, and may store the received data in the storage device.

The output device may visually/non-visually output the data processed by the quantum computing device 400, and the like. The output device may include a sound output device, a display device (e.g., display), an audio module, and/or a haptic module.

The image capture device may include a device, such as a camera and the like, for capturing still images and/or moving images, etc., and may store the captured images in the storage device. The image capture device may include a lens assembly having one more more lenses, image sensors, image signal processors, and/or flashes. The lens assembly included in a camera module may collect light emanating from a subject to be imaged.

The input device may receive data and/or instructions to be processed by the quantum computing device 400 from a user. The input device may include a control button provided on the quantum computing device 400, a touch screen of a display, a microphone, a mouse, a keyboard, and/or a digital pen (e.g., a stylus pen, etc.), and the like.

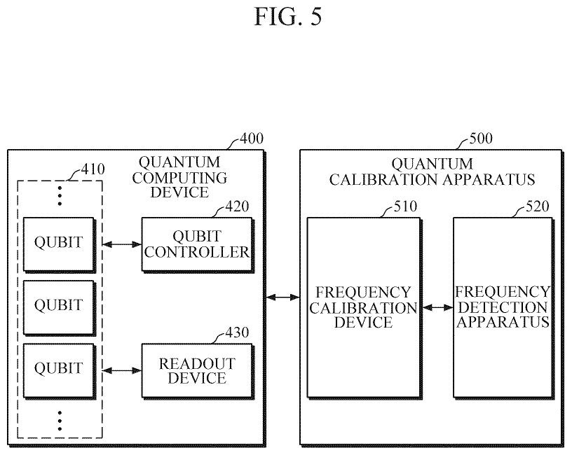

FIG. 5 is a block diagram illustrating an example in which a frequency detection apparatus is included in an apparatus for calibrating a quantum computing device.

Referring to FIG. 5, a quantum calibration apparatus 500, which is an apparatus for calibrating the quantum computing device 400, may include a frequency calibration device 510 and a frequency detection apparatus 520.

The frequency calibration device 510 may calibrate the Rabi frequency of the quantum computing device 400 and may control the frequency detection apparatus 520 to detect an optimal Rabi frequency. As described above, the frequency detection apparatus 440 may detect the Rabi frequency based on the Wasserstein distance.

The frequency detection apparatuses, memories, processors, quantum computing devices, qubits, qubit controllers, readout devices, quantum calibration apparatuses, frequency calibration devices, frequency detection apparatus 100, memory 110, processor 120, quantum computing device 400, one or more qubits 410, qubit controller 420, readout device 430, frequency detection apparatus 440, quantum calibration apparatus 500, frequency calibration device 510, and frequency detection apparatus 520 described herein, including descriptions with respect to respect to FIGS. 1-5, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in, and discussed with respect to, FIGS. 1-5 that perform the operations described in this application are performed by computing hardware, for example, by one or more processors or computers, implemented as described above implementing instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method with frequency detection, the method comprising:
setting a sample cutting parameter;
performing sampling in a sampling interval set based on the sample cutting parameter;
obtaining a Wasserstein distance between a first probability distribution and a second probability distribution for an available frequency based on a result of the sampling; and
determining a frequency, at which the obtained Wasserstein distance is minimum, as an optimal frequency.

2. The method of claim 1, wherein the first probability distribution is
$$\frac{1}{{\sum }_{j = 1}^{n} {cos}^{2} ( π {fx}_{j} )} {\sum }_{i = 1}^{n} {cos}^{2} ( π {fx}_{i} ) {δ}_{{x}_{i}} ,$$
the second probability distribution is
$$\frac{1}{{\sum }_{j = 1}^{n} \frac{{a}_{i}}{m}} {\sum }_{i = 1}^{n} \frac{{a}_{i}}{m} {δ}_{{x}_{i}} ,$$
i and j are integer indexes, f is the available frequency, m is a number of sample points, n is a number of samplings at each sample point, xᵢ is an amplitude at a sample point i, aᵢ is a number of times zero appears when samplings are performed m number of times at the sample point i, and δ is a Dirac delta function.

3. The method of claim 1, wherein the first probability distribution is
$${\sum }_{j = 1}^{n} \frac{1}{n} {δ}_{{cos}^{2}} ( π {fx}_{i} ) ,$$
the second probability distribution is
$${\sum }_{i = 1}^{n} \frac{1}{n} {δ}_{\frac{{a}_{i}}{m}} ,$$
i and j are integer indexes, f is the available frequency, m is a number of sample points, n is a number of samplings at each sample point, xᵢ is an amplitude at a sample point i, aᵢ is a number of times zero appears when samplings are performed m number of times at the sample point i, and δ is a Dirac delta function.

4. The method of claim 1, wherein the sample cutting parameter comprises a first cutting value obtained by multiplying a first value by an initial period and a second cutting value obtained by multiplying a second value by the initial period.

5. The method of claim 4, wherein the sampling interval comprises an interval between the first cutting value and the second cutting value.

6. The method of claim 4, further comprising setting a total number of samples N=m×n including the number of sample points m and the number of samplings n at each sample point,
wherein m and n are natural numbers.

7. The method of claim 6, wherein the number of sample points m and the number of samplings n at each sample point are adjusted as hyperparameters.

8. The method of claim 1, further comprising:
setting a grid search parameter; and
searching for the available frequency based on the set grid search parameter.

9. A non-transitory computer-readable storage medium storing instructions that, when executed by one or more processors, configure the one or more processors to perform the method of claim 1.

10. An apparatus with frequency detection, the apparatus comprising:
one or more processors configured to:
set a sample cutting parameter;
perform sampling in a sampling interval set based on the sample cutting parameter;
obtain a Wasserstein distance between a first probability distribution and a second probability distribution for an available frequency based on a result of the sampling; and
determine a frequency, at which the obtained Wasserstein distance is minimum, as an optimal frequency.

11. The apparatus of claim 10, wherein the first probability distribution is
$$\frac{1}{{\sum }_{j = 1}^{n} {cos}^{2} ( π {fx}_{j} )} {\sum }_{i = 1}^{n} {cos}^{2} ( π {fx}_{i} ) {δ}_{{x}_{i}} ,$$
the second probability distribution is
$$\frac{1}{{\sum }_{j = 1}^{n} \frac{{a}_{i}}{m}} {\sum }_{i = 1}^{n} \frac{{a}_{i}}{m} {δ}_{{x}_{i}} ,$$
i and j are integer indexes, f is the available frequency, m is a number of sample points, n is a number of samplings at each sample point, xᵢ is an amplitude at a sample point i, aᵢ is a number of times zero appears when samplings are performed m number of times at the sample point i, and δ is a Dirac delta function.

12. The apparatus of claim 10, wherein the first probability distribution is
$${\sum }_{j = 1}^{n} \frac{1}{n} {δ}_{{cos}^{2}} ( π {fx}_{i} ) ,$$
the second probability distribution is
$${\sum }_{i = 1}^{n} \frac{1}{n} {δ}_{\frac{{a}_{i}}{m}} ,$$
i and j are integer indexes, f is the available frequency, m is a number of sample points, n is a number of samplings at each sample point, xᵢ is an amplitude at a sample point i, aᵢ is a number of times zero appears when samplings are performed m number of times at the sample point i, and δ is a Dirac delta function.

13. The apparatus of claim 10, wherein the sample cutting parameter comprises a first cutting value obtained by multiplying a first value by an initial period and a second cutting value obtained by multiplying a second value by the initial period.

14. The apparatus of claim 13, wherein the sampling interval comprises an interval between the first cutting value and the second cutting value.

15. The apparatus of claim 10, wherein
the one or more processors are configured to set a total number of samples N=m×n including the number of sample points m and the number of samplings n at each sample point, and
m and n are natural numbers.

16. The apparatus of claim 10, wherein the one or more processors are configured to:
set a grid search parameter; and
search for the available frequency based on the set grid search parameter.

17. The apparatus of claim 10, further comprising:
one or more qubits; and
a qubit controller configured to control the one or more qubits based on the determined optimal frequency.

18. A quantum computing device comprising:
a frequency detection apparatus configured to:
perform sampling in a sampling interval set based on a sample cutting parameter;
obtain a Wasserstein distance between a first probability distribution and a second probability distribution for an available frequency based on a result of the sampling and
determine a frequency, at which the obtained Wasserstein distance is minimum, as a Rabi frequency;
one or more qubits; and
a qubit controller configured to control the one or more qubits based on the determined Rabi frequency.

19. The quantum computing device of claim 18, wherein the sample cutting parameter comprises a first cutting value obtained by multiplying a first value by an initial period and a second cutting value obtained by multiplying a second value by the initial period.

20. The quantum computing device of claim 18, wherein
the frequency detection apparatus is configured to set a total number of samples N=m×n including a number of sample points m and a number of samplings n at each sample point, and
m and n are natural numbers.
